(19) United States
(12) Patent Application Publication
(10) Pub. No.: US 2025/0174693 A1
(43) Pub. Date: May 29, 2025

(54) METHOD OF MANUFACTURING POLYMER ELECTROLYTE MEMBRANE FUEL CELL

(71) Applicants: HYUNDAI MOTOR COMPANY, SEOUL (KR); KIA CORPORATION, SEOUL (KR); FOUNDATION OF SOONGSIL UNIVERSITY-INDUSTRY COOPERATION, SEOUL (KR)

(72) Inventors: Seung Tak Noh, Yongin-si (KR); Seung Hun Kang, Suwon-si (KR); Tae Hyun Park, Seoul (KR); Young Jin Jeong, Seoul (KR); Gyo Sik Kim, Ansan-si (KR); O Been Kwon, Seoul (KR); Seok Hun Jeong, Daejeon (KR); Jae Yeon Kim, Seoul (KR); Hong Nyoung Yoo, Paju-si (KR)

(73) Assignees: HYUNDAI MOTOR COMPANY, SEOUL (KR); KIA CORPORATION, SEOUL (KR); FOUNDATION OF SOONGSIL UNIVERSITY-INDUSTRY COOPERATION, SEOUL (KR)

(21) Appl. No.: 18/646,368

(22) Filed: Apr. 25, 2024

(30) Foreign Application Priority Data
Nov. 28, 2023 (KR) 10-2023-0167711

(51) Int. Cl. H01M 8/1004; C23C 16/26; C23C 16/44; C23C 16/56; H01M 8/10

(52) U.S. Cl. CPC H01M 8/1004; C23C 16/26; C23C 16/4418; C23C 16/56; H01M 2008/1095

(57) ABSTRACT

A method of manufacturing a polymer electrolyte membrane fuel cell includes preparing an intermediate sheet comprising a fibrous carbon material, obtaining carbon sheets by performing at least one of heat treatment or acid treatment on the intermediate sheet, and manufacturing unit cells comprising an electrolyte membrane. Electrodes are located on a first surface and a second surface of the electrolyte membrane, gas diffusion layers are located on the electrodes, and the carbon sheets are interposed between the electrodes and the gas diffusion layers. Electrochemical performance of the polymer electrolyte membrane fuel cell is improved by removing impurities, such as Fe particles and amorphous carbon, from carbon sheets through heat treatment or acid treatment.

### CROSS REFERENCE TO RELATED APPLICATIONS

This application claims under 35 U.S.C. § 119(a) the benefit of priority to Korean Patent Application No. 10-2023-0167711 filed on Nov. 28, 2023, the entire contents of which are incorporated herein by reference.

BACKGROUND

### (a) Technical Field

The present disclosure relates to a method of manufacturing a polymer electrolyte membrane fuel cell. More particularly, it relates to a method of manufacturing a polymer electrolyte membrane fuel cell having improved electrochemical performance by removing impurities, such as Fe particles and amorphous carbon, from a carbon sheet through heat treatment or acid treatment.

### (b) Background Art

Fuel cells are power generation systems which produce electrical energy through electrochemical reaction between hydrogen and oxygen. The fuel cells are classified into phosphoric acid fuel cells, molten carbonate fuel cells, solid oxide fuel cells, polymer electrolyte membrane fuel cells, and alkaline fuel cells, depending on a kind of electrolyte used. These respective fuel cells are basically operated by the same principle, but types of fuels used, operating temperatures, catalysts, electrolytes, etc. of these fuel cells are different.

Thereamong, polymer electrolyte membrane fuel cells (PEMFCs) have characteristics, such as significantly high output characteristics, a low operating temperature, a short start-up time, and rapid responsiveness to a load change, compared to other fuel cells. In addition to these characteristics, polymer electrolyte membrane fuel cells (PEMFCs) have an advantage of being able to produce various ranges of output, and have a wide range of application, i.e., may be used as a portable power source, such as a power source for portable electronic devices, or a transportation power source, such as a power source for electric vehicles, as well as a distributed power source, such as a stationary power plant for houses and public buildings.

Polymer electrolyte membrane fuel cells (PEMFCs) are used in the form of a stack obtained by stacking and assembling several tens to hundreds of unit cells, so as to satisfy a required output level. The unit cell includes bipolar plates (i.e., separators), gas diffusion layers (GDLs), electrodes (i.e., an anode and a cathode), and a polymer electrolyte membrane (i.e., a proton exchange membrane), and an assembly obtained by attaching the two electrodes to the polymer electrolyte membrane is referred to as a membrane electrode assembly (MEA). The composition and performance of such an MEA may be said to be the core of polymer electrolyte membrane fuel cells.

In electrochemical reaction in a fuel cell, hydrogen supplied to an anode serving as an oxidation electrode of the fuel cell is separated into protons and electrons by hydrogen oxidation reaction (HOR), as set forth in Reaction Equation [1] below, and then, the protons migrate to a cathode serving as a reduction electrode through a membrane and the electrons are moved to the cathode through an external circuit. The protons and the electrons react with oxygen gas supplied from the outside by oxygen reduction reaction (ORR) at the cathode, and thereby, produce electricity and heat, and simultaneously produce water as a reaction by-product.

H₂→2H⁺+2e⁻, Eº=0.000 V (vs. SHE) [1]

1/2O₂+2H⁺+2e⁻→H₂O, Eº=1.229 V (vs. SHE) [2]

Here, Eº indicates standard electrode potential, and SHE indicates a standard hydrogen electrode.

Each of the electrodes, i.e., the anode and the cathode, includes a catalyst layer, and each of the GDLs includes a microporous layer including carbon particles and a substrate layer including carbon fibers. Because the structure of the microporous layer coming into contact with the catalyst layer has particulate porous characteristics similar to the structure of the catalyst layer, it is difficult to expand the electrochemical active area of the fuel cell.

Further, the substrate layer coming into contact layer the bipolar plate has porous characteristics in which the carbon fibers are irregularly arranged so as to easily discharge products obtained during a charge and discharge process, and such structural characteristics cause non-uniform contact between the bipolar plate and the GDL and may thus have an adverse effect on performance and durability of the fuel cell.

The above information disclosed in this Background section is only for enhancement of understanding of the background of the disclosure and therefore it may contain information that does not form the prior art that is already known in this country to a person of ordinary skill in the art.

### SUMMARY

In order to solve the above-described problems, a method of interposing a carbon nanotube sheet between an electrode and a gas diffusion layer or interposing a carbon nanotube sheet between gas diffusion layers has been disclosed. Chemical vapor deposition, particularly, direct spinning, is used to synthesize the carbon nanotube sheet in a large area, and Fe particles may remain in the carbon nanotube sheet due to an Fe-containing catalyst (Ferrocene, C₁₀H₁₀Fe) used in this process.

When the Fe particles remain in the carbon nanotube sheet, the Fe particles are ionized to form radicals during a process of manufacturing a membrane electrode assembly through thermal compression or a process of charging and discharging a fuel cell, and ionomers present in electrodes or an electrolyte membrane may be chemically degraded.

The present disclosure has been made in an effort to solve the above-described problems associated with the prior art, and it is an object of the present disclosure to remove Fe particles from a sheet including a fibrous carbon material, such as carbon nanotubes, by performing designated post-treatment of the sheet.

It is another object of the present disclosure to remove impurities, such as amorphous carbon, remaining in a sheet including a fibrous carbon material, such as carbon nanotubes, through designated post-treatment of the sheet.

In one aspect, the present disclosure provides a method of manufacturing a polymer electrolyte membrane fuel cell including preparing an intermediate sheet including a fibrous carbon material, obtaining carbon sheets by performing at least one of heat treatment or acid treatment of the intermediate sheet, and manufacturing unit cells including an electrolyte membrane, electrodes located on both surfaces of the electrolyte membrane, gas diffusion layers located on the electrodes, and the carbon sheets interposed between the electrodes and the gas diffusion layers.

In a preferred embodiment, preparing the intermediate sheet may be performed using direct spinning.

In another preferred embodiment, the fibrous carbon material may include one selected from the group consisting of carbon nanofibers, carbon nanotubes, vapor grown carbon fibers, and combinations thereof.

In still another preferred embodiment, porosity of the carbon sheets may be greater than or equal to porosity of the electrodes but less than or equal to porosity of the gas diffusion layers.

In yet another preferred embodiment, the porosity of the carbon sheets may be 20% to 40%. Further, an average diameter of pores in the carbon sheets may be 5 nm to 50 nm.

In still yet another preferred embodiment, as analysis results of the carbon sheets using Raman spectroscopy, a ratio I_{G}/I_{D} of a peak intensity I_{G} of a G band to a peak intensity I_{D} of a D band may be 6.5 or more.

In a further preferred embodiment, as thermogravimetric analysis results of the carbon sheets, an amount of impurities remaining in the carbon sheets may be less than 14 wt %. Particularly, the amount of impurities remaining in the carbon sheets may be less than 3 wt %.

In another further preferred embodiment, the heat treatment may be performed in a temperature range of greater than 450° C. but less than 600° C.

In still another further preferred embodiment, the acid treatment may be performed using a strong acid.

In yet another further preferred embodiment, the heat treatment and the acid treatment may be performed for 5 minutes to 30 minutes.

In another aspect, the present disclosure provides a method of manufacturing a polymer electrolyte membrane fuel cell including preparing an intermediate sheet including a fibrous carbon material, obtaining carbon sheets by performing at least one of heat treatment or acid treatment of the intermediate sheet, and manufacturing unit cells including an electrolyte membrane, electrodes located on both surfaces of the electrolyte membrane, gas diffusion layers located on the electrodes, bipolar plates located on the gas diffusion layers, and the carbon sheets interposed between the gas diffusion layers and the bipolar plates.

In a preferred embodiment, preparing the intermediate sheet may be performed using direct spinning.

In another preferred embodiment, porosity of the carbon sheets may be greater than or equal to porosity of the gas diffusion layers but less than or equal to porosity of the bipolar plates.

In still another preferred embodiment, as analysis results of the carbon sheets using Raman spectroscopy, a ratio I_{G}/I_{D} of a peak intensity I_{G} of a G band to a peak intensity I_{D} of a D band may be 6.5 or more.

In yet another preferred embodiment, as thermogravimetric analysis results of the carbon sheets, a amount of impurities remaining in the carbon sheets may be less than 14 wt %. Particularly, the amount of impurities remaining in the carbon sheets may be less than 3 wt %.

In still yet another preferred embodiment, the acid treatment may be performed using a strong acid.

In a further preferred embodiment, the method may further include performing water repellent treatment of the carbon sheets.

Other aspects and preferred embodiments of the disclosure are discussed infra.

### BRIEF DESCRIPTION OF THE FIGURES

The above and other features of the present disclosure will now be described in detail with reference to certain exemplary embodiments thereof illustrated in the accompanying drawings which are given hereinbelow by way of illustration only, and thus are not limitative of the present disclosure, and wherein:

FIG. 1 shows a schematic cross-sectional view of a polymer electrolyte membrane fuel cell according to a first embodiment of the present disclosure;

FIG. 2 shows a view schematically describing a process of synthesizing carbon nanotube fibers using direct spinning;

FIG. 3 shows a schematic cross-sectional view of a polymer electrolyte membrane fuel cell according to a second embodiment of the present disclosure;

FIG. 4 shows scanning electron microscopy (SEM) analysis results of a carbon sheet on which heat treatment and acid treatment according to the present disclosure have not been performed;

FIG. 5 shows scanning electron microscopy (SEM) analysis results of a carbon sheet on which heat treatment and acid treatment according to the present disclosure have been performed;

FIG. 6 shows Raman spectroscopy results of the carbon sheet on which both heat treatment and acid treatment according to the present disclosure have been performed and the carbon sheet on which heat treatment and acid treatment according to the present disclosure have not been performed;

FIG. 7 shows Raman spectroscopy results of a carbon sheet on which only heat treatment has been performed;

FIG. 8 shows thermogravimetric analysis results of carbon sheets according to Manufacturing Example 1 and Comparative Manufacturing Example 1;

FIG. 9 shows electrochemical performance evaluation results of fuel cells obtained by interposing carbon sheets according to Manufacturing Examples and Comparative Manufacturing Examples, manufactured at a relative humidity of 100%, between gas diffusion layers and electrodes;

FIG. 10 shows electrochemical performance evaluation results of fuel cells obtained by interposing carbon sheets according to Manufacturing Examples and Comparative Manufacturing Examples, manufactured at a relative humidity of 40%, between gas diffusion layers and electrodes;

FIG. 11 shows impedance spectroscopy analysis results of the fuel cells of FIG. 9;

FIG. 12 shows impedance spectroscopy analysis results of the fuel cells of FIG. 10;

FIG. 13 shows electrochemical performance evaluation results of fuel cells obtained by interposing the carbon sheets according to Manufacturing Examples and Comparative Manufacturing Examples, manufactured at a relative humidity of 100%, between gas diffusion layers and bipolar plates;

FIG. 14 shows electrochemical performance evaluation results of fuel cells obtained by interposing the carbon sheets according to Manufacturing Examples and Comparative Manufacturing Examples, manufactured at a relative humidity of 40%, between gas diffusion layers and bipolar plates;

FIG. 15 shows impedance spectroscopy analysis results of the fuel cells of FIG. 13; and

FIG. 16 shows impedance spectroscopy analysis results of the fuel cells of FIG. 14.

It should be understood that the appended drawings are not necessarily to scale, presenting a somewhat simplified representation of various preferred features illustrative of the basic principles of the disclosure. The specific design features of the present disclosure as disclosed herein, including, for example, specific dimensions, orientations, locations, and shapes, will be determined in part by the particular intended application and use environment.

In the figures, reference numbers refer to the same or equivalent parts of the present disclosure throughout the several figures of the drawing.

### DETAILED DESCRIPTION

The above-described objects, other objects, advantages and features of the present disclosure will become apparent from the descriptions of embodiments given hereinbelow with reference to the accompanying drawings. However, the present disclosure is not limited to the embodiments disclosed herein and may be implemented in various different forms. The embodiments are provided to make the description of the present disclosure thorough and to fully convey the scope of the present disclosure to those skilled in the art.

In the following description of the embodiments, terms, such as “including”, “comprising” and “having”, are to be interpreted as indicating the presence of characteristics, numbers, steps, operations, elements or parts stated in the description or combinations thereof, and do not exclude the presence of one or more other characteristics, numbers, steps, operations, elements, parts or combinations thereof, or possibility of adding the same. In addition, it will be understood that, when a part, such as a layer, a film, a region or a plate, is said to be “on” another part, the part may be located “directly on” the other part or other parts may be interposed between the two parts. In the same manner, it will be understood that, when a part, such as a layer, a film, a region or a plate, is said to be “under” another part, the part may be located “directly under” the other part or other parts may be interposed between the two parts.

All numbers, values and/or expressions representing amounts of components, reaction conditions, polymer compositions and blends used in the description are approximations in which various uncertainties in measurement generated when these values are obtained from essentially different things are reflected and thus it will be understood that they are modified by the term “about”, unless stated otherwise. In addition, it will be understood that, if a numerical range is disclosed in the description, such a range includes all continuous values from a minimum value to a maximum value of the range, unless stated otherwise. Further, if such a range refers to integers, the range includes all integers from a minimum integer to a maximum integer, unless stated otherwise.

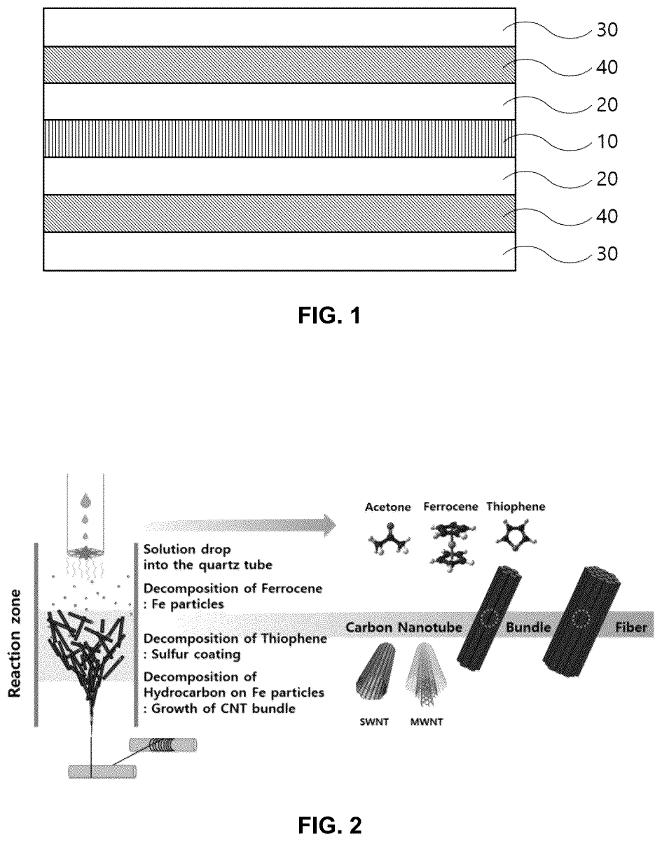

FIG. 1 is a schematic cross-sectional view of a polymer electrolyte membrane fuel cell according to a first embodiment of the present disclosure. Referring to FIG. 1, there is provided a method of manufacturing the polymer electrolyte membrane fuel cell including preparing an intermediate sheet including a fibrous carbon material, obtaining carbon sheets 40 and 40′ by performing at least one of heat treatment or acid treatment of the intermediate sheet, and manufacturing unit cells, each of which includes an electrolyte membrane 10, electrodes 20 and 20′ located on both surfaces of the electrolyte membrane 10, gas diffusion layers 30 and 30′ located on the electrodes 20 and 20′, and the carbon sheets 40 and 40′ (commonly represented hereinafter by reference numeral 40) interposed between the electrodes 20 and 20′ (commonly represented hereinafter by reference numeral 20) and the gas diffusion layers 30 and 30′. Here, each of the unit cells may further include bipolar plates (not shown) located on the gas diffusion layers 30 and 30′ (commonly represented hereinafter by reference numeral 30).

Hereinafter, “both surfaces” of any configuration may be expressed as “one surface and other surface” or “first surface and second surface.”

First, the electrolyte membrane 10 may include proton conductive polymer electrolyte membrane which is used in general unit cells for fuel cells. Electrolyte membranes may be broadly divided into an acidic type and a basic type, and an acidic type electrolyte membrane having durability which may withstand free radicals, such as hydroperoxyl (HOO) radical, generated in an energy conversion process, particularly, a perfluorinated sulfonic acid-based electrolyte membrane formed of NAFION™ (manufactured by Dupont), which has a perfluorinated group at the main chain and a sulfonic acid group at the side chain, may be used.

One of the electrodes 20 and 20′ located on one surface of the electrolyte membrane 10 may be a cathode corresponding to an air electrode, and the other of the electrodes 20 and 20′ located on the other surface of the electrolyte membrane 10 may be an anode corresponding to a fuel electrode. The electrode 20 may include a catalyst, and the catalyst may include, for example, platinum (Pt) alone, or may include an alloy of one metal selected from the group consisting of ruthenium (Ru), osmium (Os), chromium (Cr), nickel (Ni), manganese (Mg), cobalt (C), and combinations thereof, and platinum (Pt). Further, the catalyst may be supported on a carbon material.

The gas diffusion layer 30 is an element which is generally formed on the surface of the electrode 20 forming a membrane electrode assembly, and passes reaction gas flowing through the bipolar plate while distributing the reaction gas to the electrolyte membrane 10. The gas diffusion layer 30 includes a microporous layer including carbon particles and a substrate layer including carbon fibers, and the microporous layer may be disposed to face the electrode 20, and the substrate layer may be disposed to face the bipolar plate.

Here, the microporous layer may include particulate porous carbon particles, for example, carbon powder of carbon black, acetylene black carbon, or Black Pearls. Further, a mixture of a polytetrafluoroethylene (PTFE)-based hydrophobic agent and the carbon powder may be used.

The substrate layer may include irregularly arranged carbon fibers, and may have an irregular fibrous porous structure. Further, the substrate layer may further include a polytetrafluoroethylene (PTFE)-based hydrophobic agent. The substrate layer may include, for example, carbon fiber cloth, carbon fiber felt, carbon fiber paper, or the like.

The fibrous carbon material included in the intermediate sheet may be a carbon material having a fibrous porous structure, including, for example, one selected from the group consisting of carbon nanofibers, carbon nanotubes, vapor grown carbon fibers, and combinations thereof.

FIG. 2 is a view schematically describing a process of synthesizing carbon nanotube fibers using direct spinning. Referring to FIG. 2, the intermediate sheet may be prepared through direct spinning. Direct spinning is a kind of method of producing fibers from carbon nanotubes, and is mainly used to synthesize a fibrous carbon material because carbon nanotube fibers may be produced through direct spinning.

Direct spinning may indicate a process of synthesizing carbon nanotube aerogel by injecting a precursor solution including raw materials for the fibrous carbon material, a catalyst and an accelerator, and carrier gas into an electric furnace of a vertical chemical vapor deposition (CVD) apparatus at a constant rate, and then acquiring the fibrous carbon material processed in the form of fibers from the carbon nanotube aerogel through a winding roller. Here, the fibrous carbon material may be obtained in the form of a sheet.

In the process of obtaining the fibrous carbon material using direct spinning, fibrous carbon materials having various forms, thicknesses and porosities may be synthesized by adjusting the raw materials for the fibrous carbon material, the temperature of the electric furnace, the winding speed of the winding roller, and the like.

The raw materials for the fibrous carbon material may include at least one selected from the group consisting of C2 to C10 saturated and unsaturated hydrocarbons, alcohol, and ketones. The catalyst may include at least one selected from the group consisting of ferrocene, copper (Cu), chromium (Cr), molybdenum (Mo), tungsten (W), iron (Fe), cobalt (Co), nickel (Ni), ruthenium (Ru), rhodium (Rh), palladium (Pd), osmium (OS), iridium (Ir), and platinum (Pt), and may preferably include ferrocene. The accelerator may be one of thiophene and carbon disulfide. The carrier gas is not limited to specific gas as long as it is used to synthetize a fibrous carbon material using CVD and direct spinning, and for example, hydrogen (H₂) may be used.

The temperature of the electric furnace is not limited to a specific temperature, and may be, for example, 1,250° C. to 1,450° C.

Further, when the winding speed of the winding roller is increased in the process of obtaining the fibrous carbon material through direct spinning, porosity of the fibrous carbon material may be increased. The winding speed of the winding roller is not limited to a specific speed, and may be, for example, 6 m/min to 10 m/min.

The thickness of the intermediate sheet synthesized through direct spinning may be 5 μm to 40 μm.

Although, in the present disclosure, the intermediate sheet including the fibrous carbon material is prepared using direct spinning, any intermediate sheet which requires removal of impurities, such as Fe particles or amorphous carbon, remaining therein may be applied without particular limitation.

After preparing the intermediate sheet including the fibrous carbon material through such a process, at least one of heat treatment or acid treatment of the intermediate sheet may be performed. Preferably, both heat treatment and acid treatment may be performed.

The heat treatment is a process of increasing crystallinity and porosity of the carbon sheet 40 and improving electrical conductivity of the carbon sheet 40 by removing the Fe particles remaining in the intermediate sheet and suppressing production of amorphous carbon.

In one embodiment, the heat treatment may be performed in a temperature range of greater than 450° C. but less than 600° C. When the heat treatment temperature is 450° C. or lower, the temperature is excessively low, and thus amorphous carbon may not be completely removed. When the heat treatment temperature is 600° C. or higher, the intermediate sheet including the fibrous carbon material begins to burn (or oxidize), a porous structure is destroyed, and thus, the carbon sheet 40 may not serve to diffuse gas.

Further, the heat treatment may be performed for 5 minutes to 30 minutes. When the heat treatment time is 5 minutes or shorter, the heat treatment time is excessively short, and thus amorphous carbon may not be completely removed. When the heat treatment time exceeds 30 minutes, the intermediate sheet begins to locally burn, and thus, crystallinity of the fibrous carbon material may be deteriorated and electrical conductivity of the fibrous carbon material may be reduced.

In addition, a heating rate to reach the heat treatment temperature may be 5° C./min to 15° C./min, preferably 10° C./min. When the heating rate is less than 5° C./min, it takes a long time to reach the heat treatment temperature and thus processibility may be reduced, and a heat absorption amount is increased and may thus cause physical damage to the intermediate sheet. Further, when the heating rate exceeds 15° C./min, rapid thermal deformation occurs and may thus cause microstructural deformation of the intermediate sheet.

The acid treatment is a process of preventing the Fe particles remaining in the intermediate sheet from being oxidized and adversely affecting chemical durability of the electrolyte membrane 10 by removing the Fe particles.

In one embodiment, the acid treatment may be performed using a strong acid. The strong acid indicates an acid which is mostly ionized in an aqueous solution and has a pKₐ value of 0 or less, and may include, for example, hydrochloric acid (HCl), nitric acid (HNO₃), sulfuric acid (H₂SO₄), hydrogen bromide (HBr), hydrogen iodide (HI), chloric acid (HClO₃), perchloric acid (HClO₄), or the like.

When the acid treatment is performed using a weak acid having a pKₐ value which is a positive value less than the pKₐ value of water, i.e., 15.74, the Fe particles may not be completely removed. Further, when the acid treatment is performed using a super acid stronger than sulfuric acid in an aqueous solution, the intermediate sheet is locally dissolved, crystallinity of the fibrous carbon material is deteriorated, and thereby, chemical and electrical properties of the carbon sheet 40 may be deteriorated.

Further, the acid treatment may be performed for 5 minutes to 30 minutes. When the acid treatment time is 5 minutes or shorter, the acid treatment time is excessively short, and thus the Fe particles may not be completely removed. When the acid treatment time exceeds 30 minutes, the intermediate sheet begins to be locally dissolved, and thus, crystallinity of the fibrous carbon material may be deteriorated and the chemical and electrical properties of the carbon sheet 40 may be deteriorated.

In addition, the acid treatment may be performed in a temperature range of less than the boiling point of the used acid. Preferably, the acid treatment may be performed in a temperature range which is similar to the boiling point of the acid but does not exceed the boiling point of the acid.

As the acid treatment is performed in the temperature range of less than the boiling point of the used acid, the acid treatment is performed in a gas phase, and thus the acid may effectively penetrate into the intermediate sheet having fibrous porosity so as to remove the Fe particles.

As such, the carbon sheet 40 may be obtained by performing at least one of heat treatment or acid treatment, preferably both heat treatment and acid treatment, of the intermediate sheet including the fibrous carbon material.

The carbon sheet 40 obtained by the above procedure may be interposed between the electrode 20 and the gas diffusion layer 30. Here, the carbon sheet 40 may be interposed between the electrode 20 and the gas diffusion layer 30 without any additional adhesion treatment.

The unit cell of a conventional polymer electrolyte membrane fuel cell includes gas diffusion layers formed on electrodes, and the structure of microporous layers in gas diffusion layers coming into contact with the electrodes exhibits particulate porous characteristics similar to the structure of the electrodes. Since the particulate porous structure formed by aggregation of carbon particles is affected by the size of the carbon particles and the size of the carbon particles is smaller than the size of particles of the fibrous carbon material, porosity of the particulate porous structure may be lower than porosity of the fibrous porous structure formed by aggregation of the particles of the fibrous carbon material. Therefore, the unit cell of the conventional polymer electrolyte membrane fuel cell has a problem in that it is difficult to improve the electrochemical active area of the fuel cell.

The carbon sheet 40 includes the fibrous carbon material, and has the fibrous porous structure different from the particulate porous structure. The carbon sheet 40 having the fibrous porous structure has very low in-plane resistance (for example, 1 Ω/cm or less), and thus compensates for the high in-plane resistance (for example, 100 Ω/cm or more) of the electrode 20, thereby being capable of improving electrical connectivity between catalyst particles included in the electrode 20. Accordingly, the electrochemical active area may be improved, and the improved electrochemical active area may be confirmed as lower charge transfer resistance.

At the cathode of the fuel cell, water may be produced as a reaction by-product by oxygen reduction reaction (ORR). The water may be discharged via the electrode 20, the gas diffusion layer 30 and the bipolar plate.

In order to more smoothly discharge water produced at the electrode 20, capillary pressure should decrease in a direction from the electrode 20 to the bipolar plate. Because capillary pressure is inversely proportional to porosity or pore size, the porosities of the respective elements in the unit cell may increase in the direction from the electrode 20 to the bipolar plate.

The carbon sheet 40 is interposed between the electrode 20 and the gas diffusion layer 30, and thus, the porosity of the carbon sheet 40 may be greater than or equal to the porosity of the electrode 20 but may be less than or equal to the porosity of the gas diffusion layer 30.

Concretely, the porosity of the carbon sheet 40 may be 20% to 40%. When the porosity of the carbon sheet 40 is less than 20%, the porosity of the carbon sheet 40 may be less than the porosity of the electrode 20, and when the porosity of the carbon sheet 40 exceeds 40%, the porosity of the carbon sheet 40 may be greater than the porosity of the gas diffusion layer 30. When the porosity of the carbon sheet 40 is outside the above range, water produced at the electrode 20 may not be discharged smoothly.

Further, in one embodiment, the average diameter of pores in the carbon sheet 40 may be 5 nm to 50 nm. Preferably, the average diameter of the pores in the carbon sheet 40 may be 35 nm to 50 nm. When the average diameter of the pores in the carbon sheet 40 exceeds 50 nm, water may not be discharged smoothly.

In one embodiment, as analysis results of the carbon sheet 40 using Raman spectroscopy, a ratio I_{G}/I_{D}, which is the ratio of the peak intensity I_{G} of a G band to the peak intensity I_{D} of a D band, may be 6.5 or more.

The G band indicates a peak that appears at around 1580 cm⁻¹ . The G band is observed in a carbon material having a hexagonal lattice of SP² bonded carbon, such as graphite or carbon nanotubes, as a basic configuration unit, and may mean presence of a fibrous carbon material. The D band indicates a peak that appears at around 1350 cm⁻¹ . The D band is a peak caused by defects in crystals, and may mean presence of amorphous carbon with low crystallinity.

When heat treatment according to the present disclosure is performed on a carbon sheet to which no treatment has been applied, amorphous carbon is removed, and the ratio I_{G}/I_{D} of the peak intensity I_{G} of the G band to the peak intensity I_{D} of the D band may be increased.

Further, when acid treatment according to the present disclosure is performed on the carbon sheet, crystallinity of the fibrous carbon material in the carbon sheet may be maintained even though the acid treatment is applied. Therefore, the ratio of amorphous carbon in the carbon sheet on which the acid treatment according to the present disclosure has been performed may be observed to be at a similar level to that of the carbon sheet on which no acid treatment has been performed.

When the ratio I_{G}/I_{D} of the peak intensity I_{G} of the G band to the peak intensity I_{D} of the D band of the carbon sheet 40 is less than 6.5, growth of the amorphous carbon present in the carbon sheet 40 may not be completely suppressed. The upper limit of the ratio I_{G}/I_{D} of the peak intensity I_{G} of the G band to the peak intensity I_{D} of the D band of the carbon sheet 40 is not particularly limited, and may be, for example, 11 or less.

In one embodiment, as thermogravimetric analysis results of the carbon sheet 40, the amount of impurities remaining in the carbon sheet 40 may be less than 14 wt %. Preferably, the amount of the impurities remaining in the carbon sheet 40 may be less than 3 wt %.

When the amount of the impurities remaining in the carbon sheet 40 is 14 wt % or more, it will be understood that the Fe particles remaining in the carbon sheet 40 are not completely removed by the heat treatment or the acid treatment, and are oxidized in a high temperature range to generate the impurities.

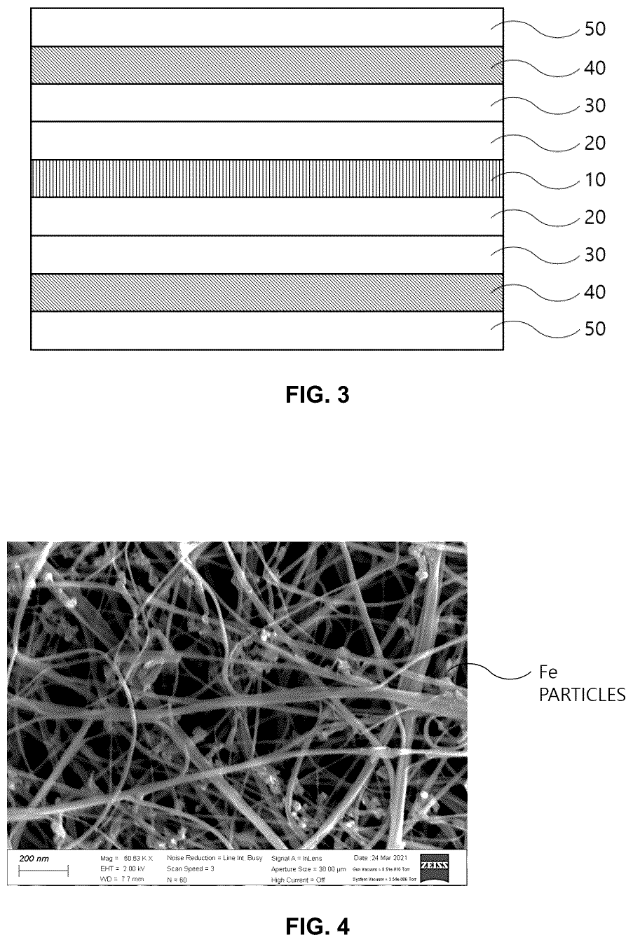

FIG. 3 is a schematic cross-sectional view of a polymer electrolyte membrane fuel cell according to a second embodiment of the present disclosure. Referring to FIG. 3, there is provided a method of manufacturing the polymer electrolyte membrane fuel cell including preparing an intermediate sheet including a fibrous carbon material, obtaining carbon sheets 40 and 40′ by performing at least one of heat treatment or acid treatment of the intermediate sheet, and manufacturing unit cells, each of which includes an electrolyte membrane 10, electrodes 20 and 20′ located on both surfaces of the electrolyte membrane 10, gas diffusion layers 30 and 30′ located on the electrodes 20 and 20′ (commonly represented hereinafter by reference numeral 20), bipolar plates 50 and 50′ located on the gas diffusion layers 30 and 30′, and the carbon sheets 40 and 40′ (commonly represented hereinafter by reference numeral 40) interposed between the gas diffusion layers 30 and 30′ (commonly represented hereinafter by reference numeral 30) and the bipolar plates 50 and 50′ (commonly represented hereinafter by reference numeral 50).

The method of manufacturing the polymer electrolyte membrane fuel cell according to the second embodiment is substantially the same as the method of manufacturing the polymer electrolyte membrane fuel cell according to the first embodiment, except that the carbon sheet 40 is interposed between the gas diffusion layer 40 and the bipolar plate 50, and a description of redundant elements will thus be omitted.

The bipolar plate 50 has the same configuration as a bipolar plate used in general unit cells for fuel cells. The bipolar plate 50 may have a flow path so as to supply reaction gases, such as hydrogen and air, outside the gas diffusion layer 30 and to discharge water produced by reaction.

The carbon sheet 40 obtained by the above procedure may be interposed between the gas diffusion layer 30 and the bipolar plate 50. Here, the carbon sheet 40 may be interposed between the gas diffusion layer 30 and the bipolar plate 50 without any additional adhesion treatment.

The substrate layer of the gas diffusion layer 30 is formed in a porous structure in which carbon fibers are combined with a PTFE-based polymer resin, and has a relatively high surface roughness (R_{z}) value (for example, 50 to 100 μm). Such a high surface roughness value of the gas diffusion layer 30 causes non-uniform contact between the bipolar plate 50 and the gas diffusion layer 30, and may thus increase ohmic resistance (Rₒₕₘ) of the unit cell and have an adverse effect on the electrochemical performance of the fuel cell.

Accordingly, the surface roughness of the carbon sheet 40 obtained by performing the heat treatment and the acid treatment of the intermediate sheet may have a lower value than the surface roughness of the gas diffusion layer 30. For example, the surface roughness of the carbon sheet 40 may be 13 μm to 15 μm.

When the carbon sheet 40 having relatively low surface roughness is interposed between the gas diffusion layer 30 and the bipolar plate 50, as in the second embodiment, non-uniform contact therebetween may be improved, and interfacial contact resistance may be reduced.

In order to more smoothly discharge water produced at the electrode 20, capillary pressure should decrease in a direction from the electrode 20 to the bipolar plate 50. Because capillary pressure is inversely proportional to porosity or pore size, the porosities of the respective elements in the unit cell may increase in the direction from the electrode 20 to the bipolar plate 50.

The carbon sheet 40 is interposed between the gas diffusion layer 30 and the bipolar plate 50, and thus, the porosity of the carbon sheet 40 may be greater than or equal to the porosity of the gas diffusion layer 30 but may be less than or equal to the porosity of the bipolar plate 50.

Concretely, the porosity of the carbon sheet 40 may be 20% to 40%. When the porosity of the carbon sheet 40 is less than 20%, the porosity of the carbon sheet 40 may be less than the porosity of the gas diffusion layer 30, and when the porosity of the carbon sheet 40 exceeds 40%, the porosity of the carbon sheet 40 may be greater than the porosity of the bipolar plate 50. When the porosity of the carbon sheet 40 is outside the above range, water produced at the electrode 20 may not be discharged smoothly.

Further, the average diameter of the pores in the carbon sheet 40 may be 5 nm to 50 nm. Preferably, the average diameter of the pores in the carbon sheet 40 may be 35 nm to 50 nm. When the average diameter of the pores in the carbon sheet 40 exceeds 50 nm, water may not be discharged smoothly.

In one embodiment, the method may further include performing water repellent treatment of the carbon sheet 40. Materials for the water repellent treatment may include a hydrophobic polymer, for example, at least one selected from the group consisting of polytetrafluoroethylene (PTFE), 2,2-bis(trifluoromethyl)-4,5-difluoro-1,3-dioxole-co-tetrafluoroethylene, fluorinated ethylene propylene (FEP), polyvinylidene fluoride (PVdF), and Fluorosarf (manufactured by Fluoro Technology).

Since heat is generated from the electrode 20 due to electrochemical reaction (oxidation or reduction), a temperature of the interface between the electrode 20 and the gas diffusion layer 30 may be higher than a temperature of the interface between the gas diffusion layer 30 and the bipolar plate 50. When the carbon sheet 40 is interposed between the gas diffusion layer 30 and the bipolar plate, as in the second embodiment, the temperature therebetween is lower than the temperature in the first embodiment, and thus, there may be a high possibility of presence of water in a liquid phase. Water discharge properties may be improved through the water repellent treatment of the carbon sheet 40.

Hereinafter, the present disclosure will be described in more detail through the following Examples and Comparative Examples. The following Examples and Comparative Examples serve merely to exemplarily describe the present disclosure, and are not intended to limit the scope and spirit of the disclosure.

### Manufacturing Example 1. Relative humidity of 100%

A precursor solution was prepared by mixing ferrocene as a transition metal source for catalysis and thiophene as an accelerator with ethanol as a raw material for a fibrous carbon material, and then sonicating the same for 2 hours.

A carbon nanotube sheet was synthesized through direct spinning by injecting the precursor solution and carrier gas (H₂, 2,200 sccm) into an electric furnace of a vertical CVD apparatus at a constant rate. Here, the winding speed of a roller through which the carbon nanotube sheet is obtained was 6 m/min to 10 m/min, and the thickness of the synthesized carbon nanotube sheet was 15 μm.

In order to remove Fe particles and amorphous carbon remaining in the carbon nanotube sheet, heat treatment of the carbon nanotube sheet was performed in an oxygen atmosphere at a temperature of 550° C. for 30 minutes by heating at a rate of 10° C./min, and then acid treatment of the carbon nanotube sheet was performed by impregnating the carbon nanotube sheet in HCl at a temperature of 80° C. for 30 minutes. A carbon sheet was manufactured by drying the heat-treated and acid-treated carbon nanotube sheet in a vacuum oven maintained at a temperature of 120° C. for 12 hours. Here, the heat treatment and the acid treatment were carried out at a relative humidity of 100%.

### Manufacturing Example 2. Relative Humidity of 40%

A carbon sheet was manufactured through the same process as in Manufacturing Example 1 except that the heat treatment and the acid treatment were carried out at a relative humidity of 40%.

### Comparative Manufacturing Example 1. Raw Carbon Sheet

A carbon sheet was manufactured through the same process as in Manufacturing Example 1 except that the heat treatment and the acid treatment were not carried out.

### Comparative Manufacturing Example 2. Relative Humidity of 100%

A carbon sheet was manufactured through the same process as in Manufacturing Example 1 except that, among the heat treatment and the acid treatment, only the heat treatment was carried out.

### Comparative Manufacturing Example 3. Relative Humidity of 40%

A carbon sheet was manufactured through the same process as in Manufacturing Example 2 except that, among the heat treatment and the acid treatment, only the heat treatment was carried out.

### EXAMPLES AND COMPARATIVE EXAMPLES

### Example 1. First Embodiment and Relative Humidity of 100%

An electrolyte membrane formed of NAFION™ (manufactured by Du Pont), an electrode slurry including a carbon supported platinum catalyst, CNT paper as gas diffusion layers, and bipolar plates having a flow path formed therein were prepared. Electrodes were formed by coating both surfaces of the electrolyte membrane with the prepared electrode slurry by spraying, and then drying the slurry. A unit cell for fuel cells was manufactured by stacking the carbon sheets according to Manufacturing Example 1 on the respective electrodes, and then sequentially stacking the gas diffusion layers and the bipolar plates having a flow path formed therein on the carbon sheets without separate adhesion treatment.

### Example 2. First Embodiment and Relative Humidity of 40%

A unit cell for fuel cells was manufactured through the same process as in Example 1 except that the carbon sheets according to Manufacturing Example 2 were stacked on the electrodes.

### Example 3. Second Embodiment and Relative Humidity of 100%

An electrolyte membrane formed of NAFION™ (manufactured by Du Pont), an electrode slurry including a carbon supported platinum catalyst, CNT paper as gas diffusion layers, and bipolar plates having a flow path formed therein were prepared. Electrodes were formed by coating both surfaces of the electrolyte membrane with the prepared electrode slurry by spraying, and then drying the slurry. A unit cell for fuel cells was manufactured by sequentially stacking the gas diffusion layers, the carbon sheets according to Manufacturing Example 1, and the bipolar plates having a flow path formed therein on the respective electrodes.

### Example 4. Second Embodiment and Relative Humidity of 40%

A unit cell for fuel cells was manufactured through the same process as in Example 3 except that the carbon sheets according to Manufacturing Example 2 were stacked on the gas diffusion layers.

### Comparative Example 1. No Carbon Sheet Interposed

An electrolyte membrane formed of NAFION™ (manufactured by Du Pont), an electrode slurry including a carbon supported platinum catalyst, CNT paper as gas diffusion layers, and bipolar plates having a flow path formed therein were prepared. Electrodes were formed by coating both surfaces of the electrolyte membrane with the prepared electrode slurry by spraying, and then drying the slurry. A unit cell for fuel cells was manufactured by sequentially stacking the gas diffusion layers and the bipolar plates having a flow path formed therein on the electrodes.

### Comparative Example 2. First Embodiment and Raw Carbon Sheet

A unit cell for fuel cells was manufactured through the same process as in Example 1 except that the carbon sheets according to Comparative Manufacturing Example 1 were stacked on the electrodes.

### Comparative Example 3. First Embodiment, Heat-Treated Carbon Sheet and Relative Humidity of 100%

A unit cell for fuel cells was manufactured through the same process as in Example 1 except that the carbon sheets according to Comparative Manufacturing Example 2 were stacked on the electrodes.

### Comparative Example 4. First Embodiment, Heat-Treated Carbon Sheet and Relative Humidity of 40%

A unit cell for fuel cells was manufactured through the same process as in Example 1 except that the carbon sheets according to Comparative Manufacturing Example 3 were stacked on the electrodes.

### Comparative Example 5. Second Embodiment and Raw Carbon Sheet

A unit cell for fuel cells was manufactured through the same process as in Example 3 except that the carbon sheets according to Comparative Manufacturing Example 1 were stacked on the gas diffusion layers.

### Comparative Example 6. Second Embodiment, Heat-Treated Carbon Sheet and Relative Humidity of 100%

A unit cell for fuel cells was manufactured through the same process as in Example 3 except that the carbon sheets according to Comparative Manufacturing Example 2 were stacked on the gas diffusion layers.

### Comparative Example 7. Second Embodiment, Heat-Treated Carbon Sheet and Relative Humidity of 40%

A unit cell for fuel cells was manufactured through the same process as in Example 3 except that the carbon sheets according to Comparative Manufacturing Example 3 were stacked on the gas diffusion layers.

### Test Example 1. Structural Analysis of Carbon Sheets

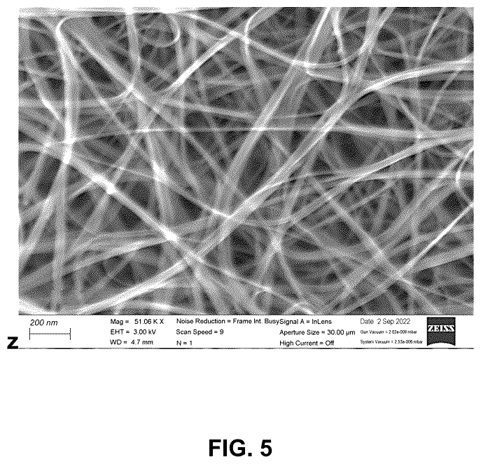

The carbon sheets according to Comparative Manufacturing Example 1 and Manufacturing Example 1 were photographed with a scanning electron microscope (SEM), and results thereof are shown in FIGS. 4 and 5, respectively.

Referring to FIG. 4, it may be seen that the carbon sheet according to Comparative Manufacturing Example 1 on which the heat treatment and the acid treatment according to the present disclosure were not performed had a large number of Fe particles attached to carbon nanotube fibers. Referring to FIG. 5, Fe particles were not observed in the carbon sheet according to Manufacturing Example 1 on which the heat treatment and the acid treatment according to the present disclosure were performed.

In addition, as a result of analysis through image processing, it may be confirmed that bundles of the carbon nanotube fibers were reduced in FIG. 5 compared to FIG. 4. Accordingly, it may be predicted that, when heat treatment and acid treatment of a carbon sheet are performed, the porosity of the carbon sheet will be improved.

### Test Example 2. Composition Analysis of Carbon Sheets

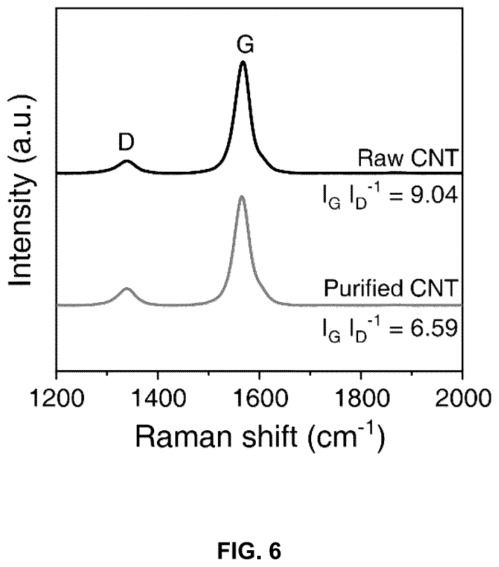

The carbon sheets according to Comparative Manufacturing Example 1 and Manufacturing Example 1 were analyzed by Raman spectroscopy, and results thereof are shown in FIG. 6. The carbon sheet according to Comparative Manufacturing Example 2 was analyzed by Raman spectroscopy, and results thereof are shown in FIG. 5.

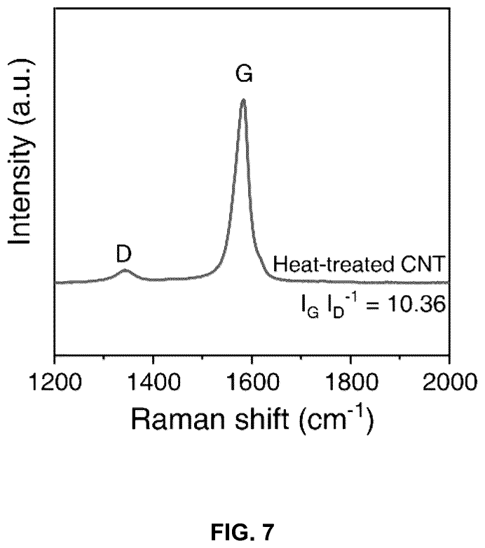

Referring to FIGS. 6 and 7, a D band with a peak appearing at about 1350 cm⁻¹ and a G hand with a peak appearing at about 1580 cm⁻¹ were observed in all the carbon sheets according to Comparative Manufacturing Examples 1 and 2 and Manufacturing Example 1. Here, the D band indicates a peak caused by defects in crystals and means presence of amorphous carbon with low crystallinity, and the G band is observed in a carbon material having a hexagonal lattice of SP² bonded carbon, such as graphite or carbon nanotubes, as a basic configuration unit, and means presence of carbon nanotubes.

As shown in FIGS. 6 and 7, the ratio I_{G}/I_{D} of the peak intensity I_{G} of the G band to the peak intensity I_{D} of the D band of the carbon sheet according to Manufacturing Example 1 was 6.59, and the respective ratios I_{G}/I_{D} of the peak intensity I_{G} of the G band to the peak intensity I_{D} of the D band of the carbon sheets according to Comparative Manufacturing Example 1 and Comparative Manufacturing Example 2 were 9.04 and 10.36, respectively.

Since the ratios I_{G}/I_{D} of the peak intensity I_{G} of the G band to the peak intensity I_{D} of the D band of the carbon sheets according to Comparative Manufacturing Example 1 and Manufacturing Example 1 are similar, it may be confirmed that growth of amorphous carbon was suppressed due to heat treatment and acid treatment of the carbon sheet.

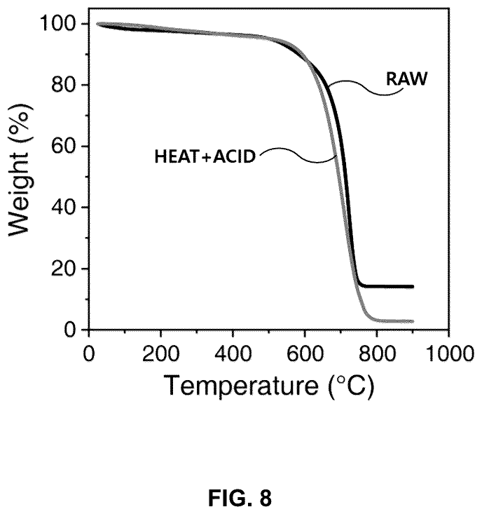

Further, theremogravimetric analysis of the carbon sheets according to Comparative Manufacturing Example 1 and Manufacturing Example 1 was performed, and results thereof are shown in FIG. 8.

Referring to FIG. 8, thermal decomposition temperatures of the carbon sheets according to Comparative Manufacturing Example 1 and Manufacturing Example 1 were similar, i.e., about 600° C., and temperatures at which thermal decomposition peaks were observed in the carbon sheets according to Comparative Manufacturing Example 1 and Manufacturing Example 1 are similar, i.e., about 750° C. and about 780° C., respectively.

However, the weight of the carbon sheet according to Comparative Manufacturing Example 1 was increased after about 750° C., and the slope thereof was increased, but the weight of the carbon sheet according to Manufacturing Example 1 was hardly increased after about 750° C., and the slope thereof was parallel. It is believed that the weight of the carbon sheet according to Comparative Manufacturing Example 1 was increased due to oxidation of Fe particles remaining in the carbon sheet at about 750° C. or higher, but Fe particles were removed from the carbon sheet according to Manufacturing Example 1 due to the heat treatment and the acid treatment.

Further, the carbon sheet according to Manufacturing Example 1 was observed to have an impurity amount of about 2.7 wt %, and the carbon sheet according to Comparative Manufacturing Example 1 was observed to have an impurity amount of about 14 wt %. It is confirmed that Fe particles and impurities caused by the Fe particles were more successfully removed from the carbon sheet according to Manufacturing Example 1 on which both the acid treatment and the heat treatment have been performed.

### Test Example 3. Performance Evaluation of Polymer Electrolyte Membrane Fuel Cells According to First Embodiment

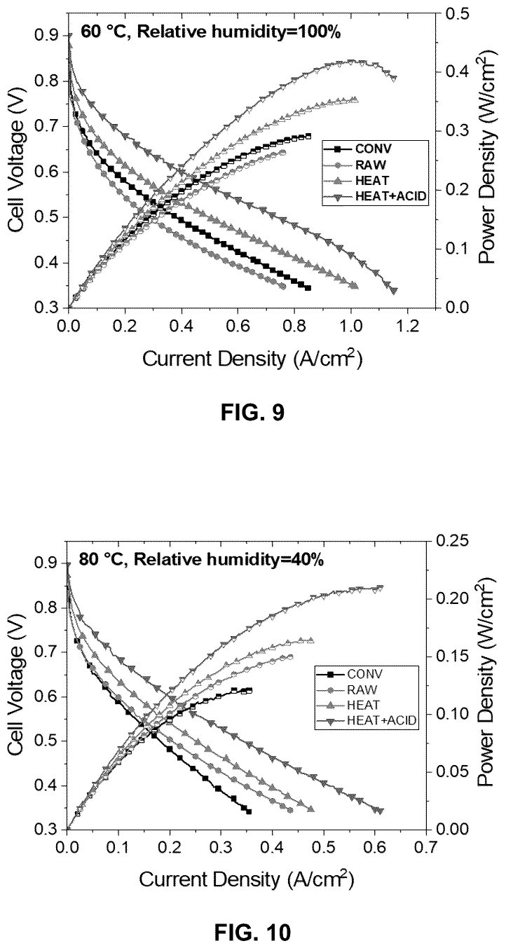

In order to confirm effects of a carbon sheet interposed between a gas diffusion layer and an electrode and heat treatment and acid treatment of the carbon sheet performed at a relative humidity of 100% on performance of a fuel cell including the carbon sheet, electrochemical performances of the unit cell according to Example 1 (HEAT+ACID), the unit cell according to Comparative Example 1 (CONV), the unit cell according to Comparative Example 2 (RAW), and the unit cell according to Comparative Example 3 (HEAT) were evaluated, and results thereof are shown in FIG. 9. Performance evaluation was conducted at a cell temperature of 60° C.

Both the maximum current density and power density of the unit cell according to Example 1 were superior to those of the unit cells according to Comparative Examples 1 to 3. Further, the maximum current density and power density of the unit cell according to Comparative Example 3 in which only the heat treatment of the carbon nanotube sheet was performed were superior to those of the unit cell according to Comparative Example 2 in which no treatment was performed and the unit cell according to Comparative Example 1 in which no carbon sheet was used.

In FIG. 9, it is expected that the electrochemical performance of the unit cell according to Comparative Example 2 including the carbon sheet is lower than that of unit cell according to Comparative Example 1 including no carbon sheet because the porosity of the carbon sheet is lowered due to Fe particles and amorphous carbon remaining in the carbon sheet and thus limits discharge of water produced during the process of charging and discharging the fuel cell.

In order to confirm effects of a carbon sheet interposed between a gas diffusion layer and an electrode and heat treatment and acid treatment of the carbon sheet performed at a relative humidity of 40% on performance of a fuel cell including the carbon sheet, electrochemical performances of the unit cell according to Example 2 (HEAT+ACID), the unit cell according to Comparative Example 1 (CONV), the unit cell according to Comparative Example 2 (RAW), and the unit cell according to Comparative Example 4 (HEAT) were evaluated, and results thereof are shown in FIG. 10. Performance evaluation was conducted at a cell temperature of 80° C.

Both the maximum current density and power density of the unit cell according to Example 2 were superior to those of the unit cells according to Comparative Examples 1, 2 and 4. Further, the maximum current density and power density of the unit cell according to Comparative Example 4 in which only the heat treatment of the carbon nanotube sheet was performed were superior to those of the unit cell according to Comparative Example 2 in which no treatment was performed and the unit cell according to Comparative Example 1 in which no carbon sheet was used.

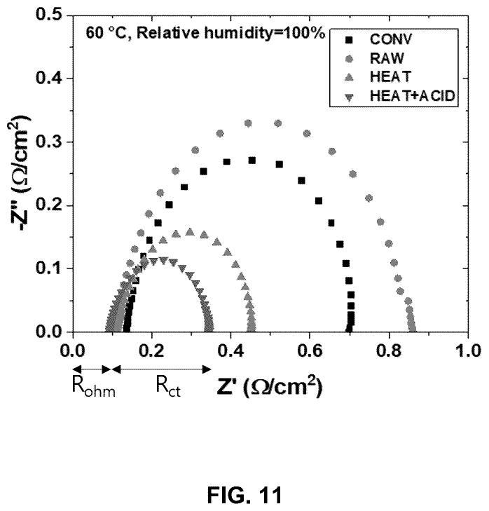

In order to confirm effects of a carbon sheet interposed between a gas diffusion layer and an electrode and heat treatment and acid treatment of the carbon sheet performed at a relative humidity of 100% on the electrochemical state of a fuel cell including the carbon sheet, the unit cell according to Example 1 (HEAT+ACID), the unit cell according to Comparative Example 1 (CONV), the unit cell according to Comparative Example 2 (RAW), and the unit cell according to Comparative Example 3 (HEAT) were analyzed using impedance spectroscopy, and results thereof are shown in FIG. 11. Analysis using impedance spectroscopy was conducted at a cell temperature of 60° C.

Referring to FIG. 11, it is confirmed that the ohmic resistance (Rₒₕₘ) and charge transfer resistance (R_{ct}) of the unit cell according to Example 1 in which both the heat treatment and the acid treatment of the carbon sheet were performed were improved compared to the unit cells according to Comparative Examples 1 to 3.

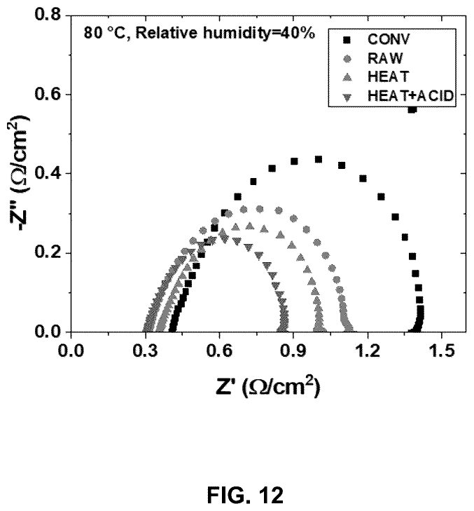

In order to confirm effects of a carbon sheet interposed between a gas diffusion layer and an electrode and heat treatment and acid treatment of the carbon sheet performed at a relative humidity of 40% on the electrochemical state of a fuel cell including the carbon sheet, the unit cell according to Example 2 (HEAT+ACID), the unit cell according to Comparative Example 1 (CONV), the unit cell according to Comparative Example 2 (RAW), and the unit cell according to Comparative Example 4 (HEAT) were analyzed using impedance spectroscopy, and results thereof are shown in FIG. 12. Analysis using impedance spectroscopy was conducted at a cell temperature of 80° C.

Referring to FIG. 12, it is confirmed that the ohmic resistance (Rₒₕₘ) and charge transfer resistance (R_{ct}) of the unit cell according to Example 2 in which both the heat treatment and the acid treatment of the carbon sheet were performed were improved compared to the unit cells according to Comparative Examples 1, 2 and 4.

### Test Example 4. Performance Evaluation of Polymer Electrolyte Membrane Fuel Cells According to Second Embodiment

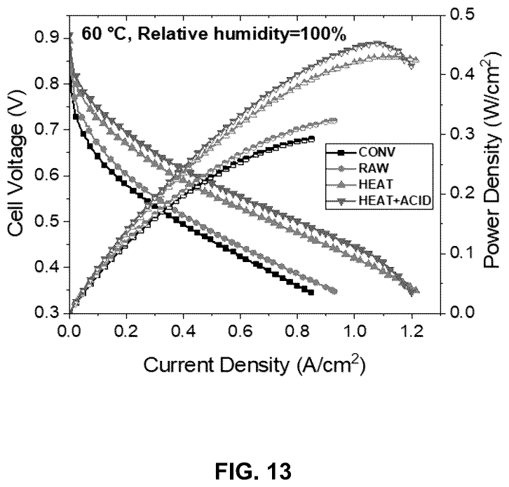

In order to confirm effects of a carbon sheet interposed between a gas diffusion layer and a bipolar plate and heat treatment and acid treatment of the carbon sheet performed at a relative humidity of 100% on performance of a fuel cell including the carbon sheet, electrochemical performances of the unit cell according to Example 3 (HEAT+ACID), the unit cell according to Comparative Example 1 (CONV), the unit cell according to Comparative Example 5 (RAW), and the unit cell according to Comparative Example 6 (HEAT) were evaluated, and results thereof are shown in FIG. 13. Performance evaluation was conducted at a cell temperature of 60° C.

Both the maximum current density and power density of the unit cell according to Example 3 were superior to those of the unit cells according to Comparative Examples 1, 5 and 6. Further, the maximum current density and power density of the unit cell according to Comparative Example 6 in which only the heat treatment of the carbon nanotube sheet was performed were superior to those of the unit cell according to Comparative Example 5 in which no treatment was performed and the unit cell according to Comparative Example 1 in which no carbon sheet was used.

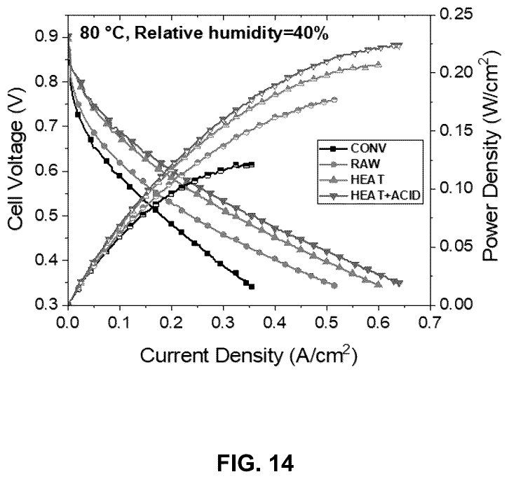

In order to confirm effects of a carbon sheet interposed between a gas diffusion layer and a bipolar plate and heat treatment and acid treatment of the carbon sheet performed at a relative humidity of 40% on performance of a fuel cell including the carbon sheet, electrochemical performances of the unit cell according to Example 4 (HEAT+ACID), the unit cell according to Comparative Example 1 (CONV), the unit cell according to Comparative Example 5 (RAW), and the unit cell according to Comparative Example 7 (HEAT) were evaluated, and results thereof are shown in FIG. 14. Performance evaluation was conducted at a cell temperature of 80° C.

Both the maximum current density and power density of the unit cell according to Example 4 were superior to those of the unit cells according to Comparative Examples 1, 5 and 7. Further, the maximum current density and power density of the unit cell according to Comparative Example 7 in which only the heat treatment of the carbon nanotube sheet was performed were superior to those of the unit cell according to Comparative Example 5 in which no treatment was performed and the unit cell according to Comparative Example 1 in which no carbon sheet was used.

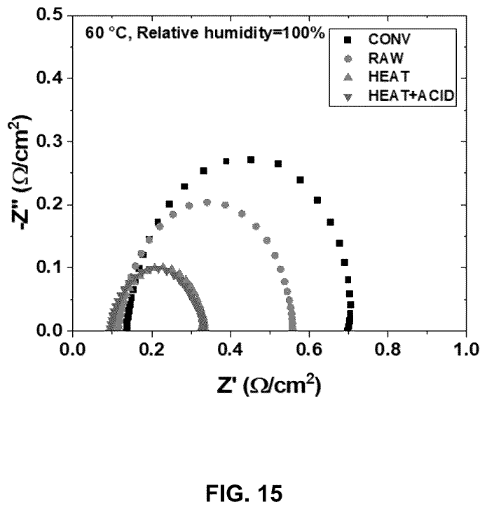

In order to confirm effects of a carbon sheet interposed between a gas diffusion layer and a bipolar plate and heat treatment and acid treatment of the carbon sheet performed at a relative humidity of 100% on the electrochemical state of a fuel cell including the carbon sheet, the unit cell according to Example 3 (HEAT+ACID), the unit cell according to Comparative Example 1 (CONV), the unit cell according to Comparative Example 5 (RAW), and the unit cell according to Comparative Example 6 (HEAT) were analyzed using impedance spectroscopy, and results thereof are shown in FIG. 15. Analysis using impedance spectroscopy was conducted at a cell temperature of 60° C.

Referring to FIG. 15, it is confirmed that the ohmic resistance (Rₒₕₘ) and charge transfer resistance (R_{ct}) of the unit cell according to Example 3 in which both the heat treatment and the acid treatment of the carbon sheet were performed were improved compared to the unit cells according to Comparative Examples 1, 5 and 6.

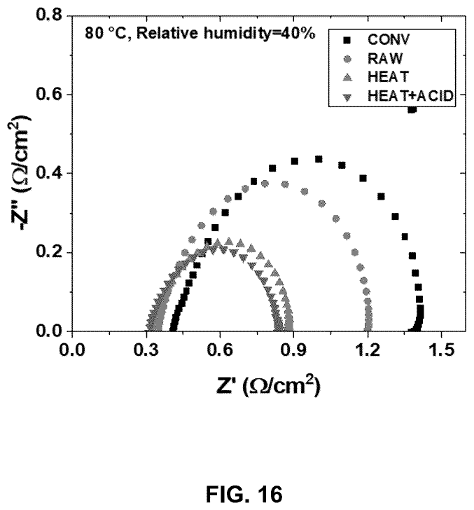

In order to confirm effects of a carbon sheet interposed between a gas diffusion layer and a bipolar plate and heat treatment and acid treatment of the carbon sheet performed at a relative humidity of 40% on the electrochemical state of a fuel cell including the carbon sheet, the unit cell according to Example 4 (HEAT+ACID), the unit cell according to Comparative Example 1 (CONV), the unit cell according to Comparative Example 5 (RAW), and the unit cell according to Comparative Example 7 (HEAT) were analyzed using impedance spectroscopy, and results thereof are shown in FIG. 16. Analysis using impedance spectroscopy was conducted at a cell temperature of 80° C.

Referring to FIG. 16, it is confirmed that the ohmic resistance (Rₒₕₘ) and charge transfer resistance (R_{ct}) of the unit cell according to Example 4 in which both the heat treatment and the acid treatment of the carbon sheet were performed were improved compared to the unit cells according to Comparative Examples 1, 5 and 7.

As is apparent from the above description, according to the present disclosure, a carbon sheet is obtained by performing at least one of heat treatment or acid treatment of an intermediate sheet including a fibrous carbon material, thereby being capable of removing impurities, such as Fe particles or amorphous carbon, remaining in the carbon sheet and preventing chemical degradation of ionomers in electrodes or an electrolyte membrane.

In addition, the carbon sheet from which the impurities, such as the Fe particles or the amorphous carbon, are removed may be interposed between the electrode and a gas diffusion layer, thereby being capable of increasing electrical connectivity between catalyst particles in the electrode and improving an electrochemical active area.

Further, the carbon sheet from which the impurities, such as the Fe particles or the amorphous carbon, are removed may be interposed between the gas diffusion layer and a bipolar plate, thereby being capable of improving non-uniform contact between the gas diffusion layer and the bipolar plate and reducing interfacial contact resistance.

The disclosure has been described in detail with reference to preferred embodiments thereof. However, it will be appreciated by those skilled in the art that changes may be made in these embodiments without departing from the principles and spirit of the disclosure, the scope of which is defined in the appended claims and their equivalents.

1. A method of manufacturing a polymer electrolyte membrane fuel cell comprising:
preparing an intermediate sheet comprising a fibrous carbon material;
obtaining carbon sheets by performing at least one of heat treatment or acid treatment on the intermediate sheet; and
manufacturing unit cells comprising an electrolyte membrane, wherein electrodes are located on a first surface and a second surface of the electrolyte membrane, gas diffusion layers are located on the electrodes, and wherein the carbon sheets are interposed between the electrodes and the gas diffusion layers.

2. The method of claim 1, wherein preparing the intermediate sheet is performed using direct spinning.

3. The method of claim 1, wherein the fibrous carbon material comprises one selected from the group consisting of carbon nanofibers, carbon nanotubes, vapor grown carbon fibers, and combinations thereof.

4. The method of claim 1, wherein a porosity of the carbon sheets is greater than or equal to a porosity of the electrodes, and the porosity of the carbon sheets is less than or equal to a porosity of the gas diffusion layers.

5. The method of claim 1, wherein a porosity of the carbon sheets is 20% to 40%.

6. The method of claim 1, wherein an average diameter of pores in the carbon sheets is 5 nm to 50 nm.

7. The method of claim 1, wherein, analysis results of the carbon sheets using Raman spectroscopy include a ratio I_{G}/I_{D} of a peak intensity I_{G} of a G band to a peak intensity I_{D} of a D band being 6.5 or more.

8. The method of claim 1, wherein thermogravimetric analysis results of the carbon sheets include an amount of impurities remaining in the carbon sheets of less than 14 wt %.

9. The method of claim 1, wherein thermogravimetric analysis results of the carbon sheets include an amount of impurities remaining in the carbon sheets of less than 3 wt %.

10. The method of claim 1, wherein the heat treatment is performed in a temperature range of greater than 450° C. and less than 600° C.

11. The method of claim 1, wherein the acid treatment is performed using a strong acid.

12. The method of claim 1, wherein the heat treatment or the acid treatment are performed for 5 minutes to 30 minutes.

13. A method of manufacturing a polymer electrolyte membrane fuel cell comprising:
preparing an intermediate sheet comprising a fibrous carbon material;
obtaining carbon sheets by performing at least one of heat treatment or acid treatment of the intermediate sheet; and
manufacturing unit cells comprising an electrolyte membrane, wherein electrodes are located on a first and second surface of the electrolyte membrane, gas diffusion layers are located on the electrodes, bipolar plates are located on the gas diffusion layers, and wherein the carbon sheets are interposed between the gas diffusion layers and the bipolar plates.

14. The method of claim 13, wherein preparing the intermediate sheet is performed using direct spinning.

15. The method of claim 13, wherein a porosity of the carbon sheets is greater than or equal to a porosity of the gas diffusion layers, and a porosity of the carbon sheets is less than or equal to a porosity of the bipolar plates.

16. The method of claim 13, wherein analysis results of the carbon sheets using Raman spectroscopy include a ratio I_{G}/I_{D} of a peak intensity I_{G} of a G band to a peak intensity I_{D} of a D band being 6.5 or more.

17. The method of claim 13, wherein thermogravimetric analysis results of the carbon sheets include an amount of impurities remaining in the carbon sheets of less than 14 wt %.

18. The method of claim 13, wherein thermogravimetric analysis results of the carbon sheets include an amount of impurities remaining in the carbon sheets of less than 3 wt %.

19. The method of claim 13, wherein the acid treatment is performed using a strong acid.

20. The method of claim 13, further comprising performing water repellent treatment of the carbon sheets.
